(19) United States
(12) Patent Application Publication
(10) Pub. No.: US 2020/0212329 A1
(43) Pub. Date: Jul. 2, 2020

(54) PHOTOELECTRIC CONVERSION FILM, PHOTOELECTRIC CONVERSION DEVICE, AND IMAGE SENSOR

(71) Applicant: Samsung Electronics Co., Ltd., Suwon-si (KR)

(72) Inventors: Naotoshi SUGANUMA, Yokohama-shi (JP); Katsunori SHIBATA, Hwaseong-si (KR); Norihito ISHII, Suwon-si (KR)

(73) Assignee: Samsung Electronics Co., Ltd., Suwon-si (KR)

(21) Appl. No.: 16/726,426

(22) Filed: Dec. 24, 2019

(30) Foreign Application Priority Data
Dec. 27, 2018 (JP) 2018-245278
Dec. 23, 2019 (KR) 10-2019-0173428

(51) Int. Cl. H01L 51/42; H01L 51/44; H01L 27/146

(52) U.S. Cl. CPC H01L 51/4206; H01L 27/14645; H01L 51/4273; H01L 51/441

(57) ABSTRACT

Provided is a photoelectric conversion film having sufficient sensitivity to near-infrared light and capable of reducing dark current. The photoelectric conversion film includes a p-type organic semiconductor, which is a near-infrared light absorbing colorant. The photoelectric conversion film has an absorption coefficient of light of less than or equal to 0.13 with respect to the wavelength of 1,000 nm at a thickness of 100 nm of the film.

### CROSS-REFERENCE TO RELATED APPLICATION

This application claims priority to and the benefit of Japanese Patent Application No. 2018-245278 filed in the Japanese Patent Office on Dec. 27, 2018, and of Korean Patent Application No. 10-2019-0173428 filed in the Korean Intellectual Property Office on Dec. 23, 2019, the entire contents of which are incorporated herein by reference.

### BACKGROUND

### 1. Field

A photoelectric conversion film, a photoelectric conversion device, and an image sensor are disclosed.

### 2. Description of Related Art

Currently, silicon photodiodes are used as a photoelectric conversion device (light receiving device) that converts light information into electric information. The photoelectric conversion device may be applied to an image sensor. Recently, an image sensor capable of sensing near-infrared light region is highly required in crime prevention, transportation, and the like. The image that senses near-infrared light region may have various applications in 3-dimensional scanner, iris recognition, noctovision (e.g., night vision) camera, a camera for vehicle, and the like.

However, the silicon that is comprised of a silicon photodiode has a small absorption coefficient of light with respect to the near-infrared light region, and thus, cannot have sufficient sensitivity to the near-infrared light region. Therefore, a research for a p-type organic semiconductor having a large absorption coefficient of light with respect to the near-infrared light region and selectivity for a specific wavelength region of absorption depending on its specific molecular structure is performed (for example, see Patent Reference 1 below).

### PRIOR ART DOCUMENTS

### Patent Reference

Japanese Patent Laid-Open Publication No. 2016-225456

### SUMMARY

However, the photoelectric conversion device according to Patent Reference 1 cannot sufficiently reduce the dark current.

Therefore, there are needs for a photoelectric conversion film that has sufficient sensitivity to near-infrared light, while reducing dark current.

An embodiment provides a photoelectric conversion film that includes a p-type organic semiconductor, which is a near-infrared light absorbing colorant, and has an absorption coefficient of light of less than or equal to about 0.13 at a thickness of 100 nanometers (nm).

Another embodiment provides a photoelectric conversion device that includes a photoelectric conversion film according to an embodiment.

Still another embodiment provides an image sensor that includes a photoelectric conversion device according to an embodiment.

The photoelectric conversion film according to an embodiment has sufficient sensitivity to near-infrared light region, while capable of reducing dark current.

### BRIEF DESCRIPTION OF THE DRAWINGS

FIG. 1 is a schematic cross-sectional view showing an example of a photoelectric conversion device according to an embodiment.

FIG. 2 is a schematic cross-sectional view showing another example of a photoelectric conversion device according to an embodiment.

FIG. 3 is a schematic cross-sectional view showing a first example of an image sensor according to an embodiment.

FIG. 4 is a schematic cross-sectional view showing a second example of an image sensor according to an embodiment.

FIG. 5 is a schematic cross-sectional view showing a third example of an image sensor according to an embodiment.

FIG. 6 is a schematic perspective view showing a third example of an image sensor according to an embodiment.

FIG. 7 is a schematic cross-sectional view showing a fourth example of an image sensor according to an embodiment.

FIG. 8 is a schematic cross-sectional view showing a fifth example of an image sensor according to an embodiment.

FIG. 9 is a schematic perspective view showing a fifth example of an image sensor according to an embodiment.

### DETAILED DESCRIPTION

Hereinafter, embodiments of the present disclosure are described in detail.

Hereinafter, in drawings, in order to clearly express a plurality of layers and regions, the thickness is enlarged. In addition, in drawings, in order to demonstrate these embodiments clearly, parts which are unnecessary for description are omitted. In addition, throughout the specification, the same symbols are used for the same or similar constituent elements.

If a part of layers, films, areas, plates, and the like is said to be “on top” of another part, the part may be “directly on” another part and another part may exist between a part and another part. On the contrary, when a part is “directly on” another part, it means that there is no other part between one part and another part.

FIG. 1 shows an example of a photoelectric conversion device according to an embodiment.

Photoelectric conversion device 100 includes a (organic) photoelectric conversion film 30 formed between first electrode 10 and second electrode 20.

At least one of first electrode 10 and second electrode 20 is a light-transmitting electrode that may transmit near-infrared light.

Examples of the material constituting the light-transmitting electrode include, for example, a conductive material such as indium tin oxide (ITO), indium zinc oxide (IZO), AZO, FTO, SnO₂, TiO₂, ZnO₂, and the like.

The light-transmitting electrode may be formed as a single layer or a plurality of layers stacked.

When first electrode 10 or second electrode 20 is a non-light-transmitting electrode that does not transmit near-infrared light, a material constituting the non-light-transmitting electrode may include, for example a metal such as aluminum (Al), copper, gold, silver, and the like, or polysilicon that is doped with impurities to have conductivity, and the like.

When forming first electrode 10 and second electrode 20, various methods may be applied depending on the used material.

For example, when an ITO electrode is formed, an electron beam method, a sputtering method, a resistive thermal deposition method, a chemical reaction method (sol-gel method, etc.), a method of coating dispersion of indium tin oxide, and the like may be used.

In addition, when first electrode 10 and second electrode 20 are formed, UV-ozone treatment, plasma treatment, or the like may be performed.

Herein, first electrode 10 may be an electrode collecting holes of charges generated in photoelectric conversion film 30. In addition, second electrode 20 may be an electrode collecting electrons of charges generated in photoelectric conversion film 30.

By applying a bias voltage between first electrode 10 and second electrode 20, it is possible to transfer holes of charges generated in photoelectric conversion film 30 to first electrode 10, and to transfer the electrons to second electrode 20.

Here, when photoelectric conversion device 100 is applied to an image sensor which is described below, converted voltage signals may be read according to amounts of holes transferred to first electrode 10. Thereby, near-infrared light may be converted into a voltage signal and taken out.

In addition, a bias voltage may be applied to collect electrons from first electrode 10 and to collect holes from second electrode 20.

Photoelectric conversion film 30 includes a p-type organic semiconductor, but it may also include a p-type organic semiconductor, as well as an n-type organic semiconductor.

Here, when photoelectric conversion film 30 includes a p-type organic semiconductor and an n-type organic semiconductor, two layers, one of which is a layer including a p-type organic semiconductor but not including an n-type organic semiconductor, and the other of which is a layer including an n-type organic semiconductor but not including a p-type organic semiconductor, may adhere to each other to form photoelectric conversion film 30, or a layer including both a p-type organic semiconductor and an n-type organic semiconductor may form photoelectric conversion film 30.

Photoelectric conversion film 30 generates excitons when receiving near-infrared light. After the excitons are separated into holes and electrons, the holes are transferred to first electrode 10, and the electrons are transferred to second electrode 20, whereby, current flows in photoelectric conversion device 100.

The p-type organic semiconductor is the near infra-red light absorbing colorant. Therefore, photoelectric conversion film 30 has a maximum absorption wavelength in the near infra-red light region, and sufficient sensitivity to near infra-red light region.

In the context of the specification and claims, the near infra-red light region indicates the region in the range of 780 nanometers (nm) to 1,000 nm.

Photoelectric conversion film 30 has an absorption coefficient of light of less than or equal to about 0.13 with respect to the wavelength of 1,000 nm at a thickness of 100 nm. For example, the absorption coefficient of light may be less than or equal to about 0.12, less than or equal to about 0.11, less than or equal to about 0.10, less than or equal to about 0.09, less than or equal to about 0.08, less than or equal to about 0.07, less than or equal to about 0.06, or less than or equal to about 0.05, and is not limited thereto. When the absorption coefficient of light with respect to the wavelength of 1,000 nm at a thickness of 100 nm exceeds 0.13, dark current may not sufficiently be reduced.

Further, the absorption coefficient of light of photoelectric conversion film 30 with respect to the wavelength of 1,000 nm at a thickness of 100 nm may be controlled by the type of p-type organic semiconductor and n-type organic semiconductor included in the photoelectric conversion film, or the volume ratio between the p-type organic semiconductor and n-type organic semiconductor.

The difference between ionization potential and electron affinity of the photoelectric conversion film may be greater than or equal to 1.07 electron Volt (eV). For example, the difference between ionization potential and electron affinity of the photoelectric conversion film may be greater than or equal to 1.08 eV, greater than or equal to 1.09 eV, greater than or equal to 1.10 eV, greater than or equal to 1.11 eV, greater than or equal to 1.12 eV, greater than or equal to 1.13 eV, greater than or equal to 1.15 eV, greater than or equal to 1.17 eV, greater than or equal to 1.20 eV, greater than or equal to 1.22 eV, greater than or equal to 1.25 eV, greater than or equal to 1.27 eV, greater than or equal to 1.30 eV, greater than or equal to 1.32 eV, greater than or equal to 1.35 eV, greater than or equal to 1.37 eV, greater than or equal to 1.40 eV, greater than or equal to 1.42 eV, or greater than or equal to 1.43 eV, but is not limited thereto. When the difference between the ionization potential and electron affinity of the photoelectric conversion film is greater than or equal to 1.07 eV, dark current may further be reduced.

The p-type organic semiconductor (near infrared light absorbing colorant) is not specifically limited, may be, for example, a cyanine compound, a dipyrromethene compound, a squarilium compound, a diimmonium compound, a dithioenyl complex, or the like, and they may be used alone or may be in combination of two or more. Among them, a cyanine compound may be used in a view of conversion efficiency of the photoelectric conversion film.

Examples of the cyanine compound may include, for example, a cyanine compound, such as, zinc phthalocyanine, Mn (II) phthalocyanine, or the like; a naphthalocyanine compound, such as, silicon 2,3-naphthalocyanine bis(tri-hexyl silyl oxide), tin 2,3-naphthalocyanine bis(tri-hexyl silyl oxide), tin 2,3-naphthalocyanine bis(tri-butyl siliyl oxide), tin 2,3-naphthalocyanine bis(tri-methyl silyl oxide), or the like, and are not limited thereto.

Examples of the cyanine compound are as below:

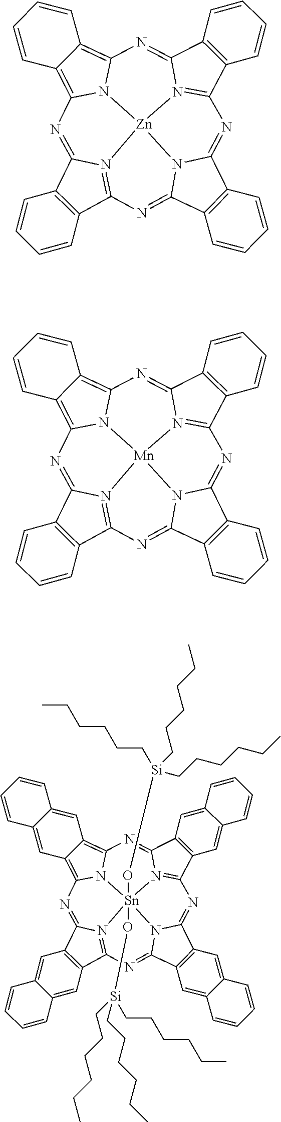

Examples of the dipyrromethene compound may include, for example, dipyrromethene boron complex, di-benzo pyrromethene boron complex, or the like, and are not limited thereto.

Examples of the dipyrromethene compound are as below:

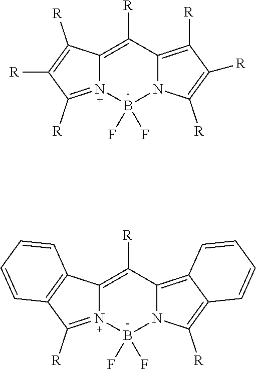

Examples of the squarilium compound may include, for example, 2,4-bis(8-hydroxy-1,1,7,7-tetramethyl zulorydin-9-yl) squarane, and the like, and are not limited thereto.

An example of the squarilium compound is as below:

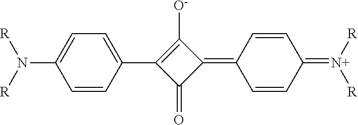

Examples of the diimmonium compound may include, for example, N,N,N′,N′-tetrakis[p-bis(cyclohexylmethyl)aminophenyl]-p-phenylene diimmonium salt, and the like, and are not limited thereto.

An example of the diimmonium compound is as below:

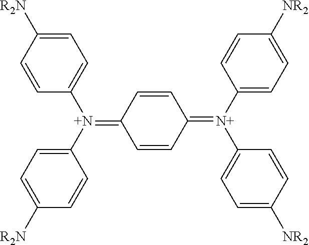

In the chemical formulae of the dipyrromethene compound, the squarilium compound, and the diimmonium compound, R and R₂ are independently hydrogen atom or a substituent, wherein the substituent is not particularly limited to a specific substituent. For example, the substituent may include deuterium atom, an halogen atom, an alkyl group (including a cycloalkyl group, a bicycloalkyl group, and a tricycloalkyl group), an alkyenyl group (including a cycloalkenyl group and a bicycloalkenyl group), an alkynyl group, an aryl group, a heterocyclic group, cyano group, hydroxyl group, nitro group, carboxyl group, alkoxy group, aryloxy group, a silyloxy group, a heterocyclic oxy group, an acyloxy group, a carbamoyloxy group, an alkoxycarbonyloxy group, an aryloxycarbonyloxy group, an amino group (including an anilino group), an ammonio group, an acylamino group, an aminocarbonylamino group, an alkoxycarbonylamino group, an aryloxycarbonylamino group, a sulfamoyl amino group, an alkylsufonylamino group, an arylsulfonylamino group, mercapto group, an alkylthio group, an arylthio group, a heterocyclicthio group, a sulfamoyl group, a sulfo group, an alkylsulfinyl group, an arylsulfinyl group, an alkylsulfonyl group, an arylsulfonyl group, an acyl group, an aryloxycarbonyl group, an alkoxycarbonyl group, a carbamoyl group, an aryl azo group, a heterocyclic azo group, an imide group, a phosphine group, a phosphinyl group, a phosphinyloxy group, a phosphinylamino group, a phosphone group, a silyl group, a hydrazine group, ureide group, a boronic acid group (—B(OH)₂), a phosphate group (—OPO(OH)₂), a sulfate group (—OSO₃H), or any other known substituents.

Examples of the dithioenyl complex may include, for example, bis(4-dimethylaminodithiobenzyl) nickel (II), bis[4,4′-dimethoxy (dithiobenzyl)] nickel (II), and the like, and are not limited thereto.

An example of the dithioenyl complex is as below:

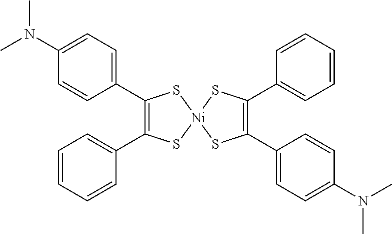

As for the n-type organic semiconductor, it may be any one as long as it forms pn junction with the p-type organic semiconductor, and is not particularly limited, but for example, sub-phthalocyanine, fullerene and a derivative thereof, or thiophene and a derivative thereof, and it may be used alone or in combination of two or more. Among them, fullerene and/or the derivative thereof may be included in view of the conversion efficiency of the photoelectric conversion film.

Examples of the fullerene include, for example, C50, C60, C70, C76, C78, C80, C82, C84, C90, C96, C240, C540, and the like, and are not limited thereto.

The derivative of the fullerene include fullerene which is substituted by a substituent.

Examples of the substituent may include, for example, an alkyl group, an aryl group, a heterocyclic group, and the like, but are not limited thereto.

The alkyl group may be linear, branched, or a cyclic alkyl group.

The linear alkyl group may include, for example, a methyl group, an ethyl group, a propyl group, a butyl group, a pentyl group, a hexyl group, a heptyl group, an octyl group, a nonyl group, a decyl group, an undecyl group, a dodecyl group, a tridecyl group, a tetradecyl group, a pentadecyl group, and the like, but is not limited thereto. For example, the linear alkyl group may be a methyl group, an ethyl group, a propyl group, a butyl group, an octyl group, a decyl group, a pentadecyl group, and the like.

Examples of the branched alkyl group may include, but are not limited to, for example, an isopropyl group, an isobutyl group, a tert-butyl group, and the like.

Examples of the cyclic alkyl group include, but are not limited to, for example, a cyclopropyl group, a cyclobutyl group, a cyclopentyl group, a cyclohexyl group, a cycloheptyl group, a cyclooctyl group, a cyclononyl group, a cyclodecyl group, and the like. For example, the cyclic alkyl group may be a cyclobutyl group, a cyclopentyl group, a cyclohexyl group, a cycloheptyl group, and the like.

The carbon number of the linear or branched alkyl group may be 1 to 30, for example, 1 to 20, for example, 1 to 18, 1 to 16, 1 to 14, 1 to 12, 1 to 10, 1 to 8, 1 to 7, 1 to 6, 1 to 5, 1 to 4, or 1 to 3, but is not limited thereto.

The carbon number of the cyclic alkyl group may be 3 to 30, for example, 3 to 20, 3 to 18, 3 to 16, 3 to 14, 3 to 12, 3 to 10, 3 to 8, or 3 to 6, but is not limited thereto.

The aryl group may be a monocyclic, non-condensed polycyclic, or condensed polycyclic aryl group.

Examples of the monocyclic aryl group include, but are not limited to, for example a phenyl group.

Examples of the non-condensed polycyclic aryl group include, but are not limited to, for example, a biphenyl group, a terphenyl group, a quaterphenyl group, a quinquephenyl group, and a ceciphenyl group.

The condensed polycyclic aryl group may include, for example, a naphthyl group, an anthryl group, a phenanthryl group, a triphenylenyl group, a fluorenyl group, a fluoranthenyl group, an indenyl group, a pyrenyl group, an acetonaphtenyl group, a bisphenylfluorenyl group, a 9-(9-fluorenyl) fluorenyl group, and the like.

The ring-forming carbon number of the aryl group of the monocyclic, non-condensed polycyclic, or condensed polycyclic may be 6 to 50, for example, 6 to 40, 6 to 30, 6 to 20, 6 to 18, 6 to 14, or 6 to 10, but is not limited thereto.

The monocyclic heterocyclic group may include, for example, a pyrrolyl group, an imidazolyl group, a pyrazolyl group, an oxazolyl group, an isoxazolyl group, an oxadiazolyl group, a thiazolyl group, a furanyl group, a pyranyl group, a thienyl group, a pyridyl group, a pyrazyl group, a pyrimidinyl group, a pyridazinyl group, a triazinyl group, a quinolyl group, an isoquinolyl group, and the like, but is not limited to thereto.

The polycyclic heterocyclic group may include, for example, a benzo (pyridyl) furanyl group, a benzofuranyl group, a benzothienyl group, an indryl group, a carbazolyl group, a carbolinyl group, a phenantridinyl group, an acridinyl group, a perimidinyl group, a phenanthrolinyl group, a benzooxazolyl group, a benzothiazolyl group, a quinoxalyl group, a benzoimidazolyl group, a pyrazolyl group, a dibenzofuranyl group, a dibenzothienyl group, and the like, but is not limited to thereto.

The ring-forming carbon number of the monocyclic or polycyclic heterocyclic group may be 4 to 50, for example, 4 to 40, 4 to 30, 4 to 20, 5 to 50, 5 to 40, 5 to 30, 5 to 20, 5 to 15, or 5 to 10, but is not limited thereto.

Photoelectric conversion film 30 may be formed of a single layer or a plurality of layers stacked.

Photoelectric conversion film 30 consisting of a single layer may be a p-type semiconductor layer, an intrinsic semiconductor layer, and the like.

A stack structure of photoelectric conversion film 30 in which a plurality of layers are stacked may include, for example, a p-type semiconductor layer/intrinsic semiconductor layer, an intrinsic semiconductor layer/n-type semiconductor layer, a p-type semiconductor layer/intrinsic semiconductor layer/n-type semiconductor layer, a p-type semiconductor layer/n-type semiconductor layer, and the like.

The intrinsic semiconductor layer may include a p-type organic semiconductor, and an n-type organic semiconductor.

A volume ratio of the n-type organic semiconductor to the p-type organic semiconductor in the intrinsic semiconductor layer may be about 0.01 to about 100, for example, about 0.01 to about 98, about 0.01 to about 95, about 0.02 to about 95, about 0.02 to about 90, or about 0.05 to about 90. Thereby, the conversion efficiency of photoelectric conversion film 30 may further be improved.

The p-type semiconductor layer may include a p-type organic semiconductor.

The n-type semiconductor layer includes an n-type organic semiconductor.

A thickness of photoelectric conversion film 30 may be about 1 nm to about 800 nm, for example, about 1 nm to about 700 nm, about 3 nm to about 700 nm, about 5 nm to about 700 nm, about 5 nm to about 600 nm, about 5 nm to about 500 nm, about 5 nm to about 450 nm, about 5 nm to about 400 nm, about 5 nm to about 350 nm, about 10 nm to about 800 nm, about 10 nm to about 700 nm, about 10 nm to about 600 nm, about 10 nm to about 500 nm, and the like, but is not limited thereto. By adjusting the thickness of the photoelectric conversion film 30 within the ranges, the conversion efficiency of the photoelectric conversion film 30 may further be improved.

Photoelectric conversion film 30 may be formed by a dry film-forming method, a resistive thermal deposition method, but may also be formed by a wet film forming method.

The dry film-forming method may include, for example, a vacuum deposition method.

Specific examples of the vacuum deposition method may include an electron beam method, a sputtering method, a resistive thermal deposition method, and the like, but are not limited thereto.

The wet film-forming method may include, for example, a solution coating method.

Specific examples of the solution coating method may include a casting method, a spin coating method, a dip coating method, a blade coating method, a wire bar coating method, a spray coating method, an inkjet printing method, a screen printing method, an offset printing method, an iron plate printing method, or the like, but is not limited thereto.

Specific examples of patterning methods when patterning of the photoelectric conversion film 30 is required may include, but are not limited to, a resist etching method, a laser removal method, or the like.

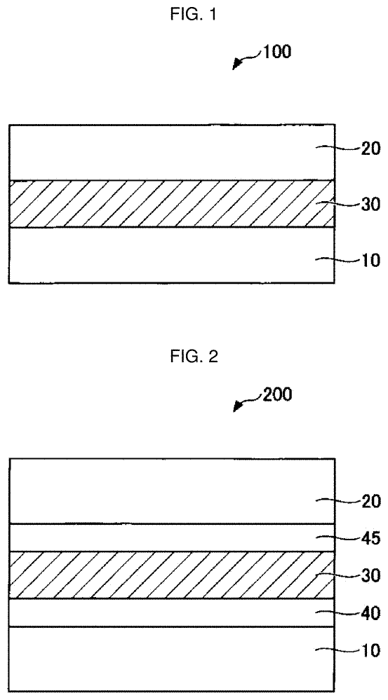

FIG. 2 shows another example of a photoelectric conversion device according to an embodiment.

Photoelectric conversion device 200 is the same as photoelectric conversion device 100, except that electron blocking layer 40 and hole blocking layer 45 are further formed between first electrode 10 and photoelectric conversion film 30 and second electrode 20 and photoelectric conversion film 30, respectively.

Electron blocking layer 40 limits and/or suppresses injection of electrons into photoelectric conversion film 30 from first electrode 10, and also limits and/or suppresses the movement of electrons generated from photoelectric conversion film 30 to first electrode 10.

Hole blocking layer 45 limits and/or suppresses the injection of holes into photoelectric conversion film 30 from second electrode 20, and also limits and/or suppresses the movement of the holes generated in photoelectric conversion film 30 to second electrode 20.

Examples of the material constituting electron blocking layer 40 may include poly(3,4-ethylenedioxythiophene):poly(styrenesulfonate) (PEDOT:PSS), polyarylamine, poly(N-vinylcarbazole), polyaniline, polypyrrole, N,N,N′,N′-tetrakis(4-methoxyphenyl) benzidine (TPD), 4,4′-bis[N-(1-naphthyl)-N-phenyl-amino] biphenyl (α-NPD), m-MTDATA, 4,4′,4″-tris(N-carbazoleyl) triphenylamine (TCTA), and the like, and are not limited thereto. These materials may be used alone or in a combination of two or more types.

Examples of the material constituting hole blocking layer 45 may include for example naphthalene-1,4,5,8-tetracarbonic acid dianhydride (NTCDA), bathocuproine (BCP), LiF, Alq3, Gaq3, Inq3, Znq2, Zn(BTZ)(2), BeBq2, and the like, but are not limited to these materials. These materials may be used alone or in a combination of two or more types.

Meanwhile, one or more of electron blocking layer 40 or hole blocking layer 45 may be omitted.

In addition, a bias voltage may be applied so as to collect electrons from first electrode 10 and to collect holes from second electrode 20. In this case, instead of electron blocking layer 40 and hole blocking layer 45, hole blocking layer 40 and electron blocking layer 45 may be formed, respectively.

The photoelectric conversion device according to an embodiment may be applied to an image sensor, a solar cell, a photodetector, a photosensor, a photodiode, and the like.

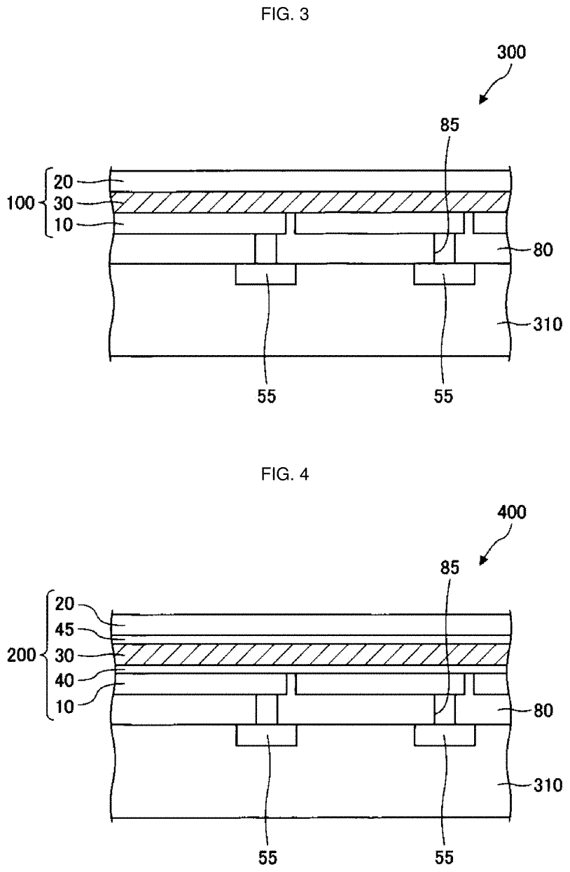

FIG. 3 shows one example of an image sensor according to an embodiment.

Image sensor 300 includes semiconductor substrate 310, an insulation layer 80, and photoelectric conversion device 100.

Semiconductor substrate 310 may be a silicon substrate in which transmission transistor and charge storage 55 are integrated. Herein, transmission transistor and charge storage 55 are integrated per pixel, charge storage 55 is electrically connected to the photoelectric conversion device 100, and the information of charge storage 55 is transmitted by the transmission transistor.

Metal wires and pads are provided on semiconductor substrate 310.

Materials of the metal wires and pads are not particularly limited if they reduce delay of the signals, but may include, for example, a metal having low resistivity, such as, aluminum (Al), copper (Cu), silver (Ag), an alloy thereof, and the like.

Insulation layer 80 is formed on semiconductor substrate 310 on which the metal wires and pads are formed.

The material constituting insulation layer 80 may include an inorganic insulating material such as silicon oxide, silicon nitride, and the like, a material having a low dielectric constant (low-k material), such as, SiC, SiCOH, SiCO, SiOF, and the like.

Insulation layer 80 is formed with contact holes for exposing the pad and through-hole 85 for exposing charge storage 55 of each pixel.

Photoelectric conversion device 100 is formed on insulation layer 80.

Photoelectric conversion device 100 includes first electrode 10, photoelectric conversion film 30, and second electrode 20, and second electrode 20 is a light-transmitting electrode capable of transmitting near-infrared light. Therefore, when light including near-infrared light is incident from second electrode 20 side, near-infrared light is absorbed in photoelectric conversion film 30 to be photo-electrically converted.

A band pass filter may be installed in the upper surface of photoelectric conversion device 100 that transmits near-infrared light alone.

FIG. 4 shows a second example of an image sensor according to an embodiment.

Image sensor 400 has the same configuration as image sensor 300 except that photoelectric conversion device 200 is applied instead of photoelectric conversion device 100.

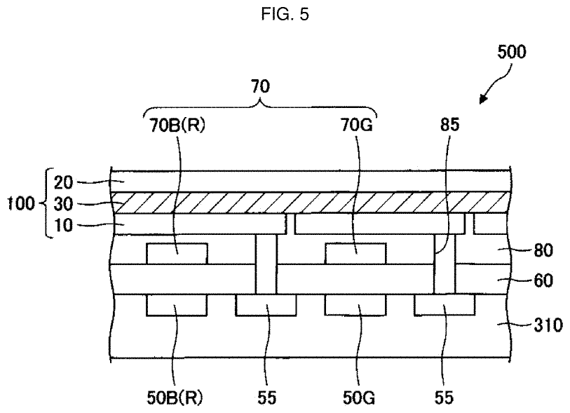

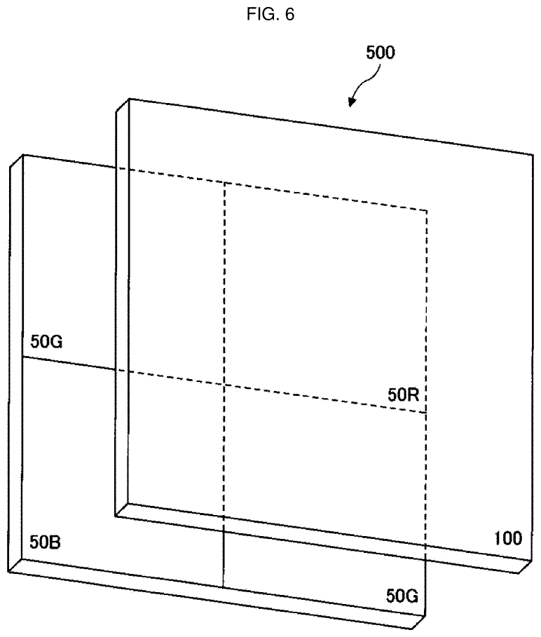

FIGS. 5 and 6 show a third example of the image sensor according to an embodiment is presented.

Image sensor 500 includes semiconductor substrate 310, lower insulation layer 60, color filter layer 70, upper insulation layer 80, and photoelectric conversion device 100.

Semiconductor substrate 310 is a silicon substrate in which photosensitive devices 50G, 50B, and 50R, a transmission transistor, and charge storage 55 are integrated. Here, photosensitive devices 50G, 50R, and 50B are silicon photodiodes. In addition, photosensitive devices 50G, 50B, and 50R, the transmission transistor, and charge storage 55 are integrated per pixel, and photosensitive devices 50G, 50B, and 50R are included in the green pixel, the blue pixel, and the red pixel, respectively. Charge storage 55 is included in the near-infrared pixel.

Photosensitive elements 50G, 50B, and 50R sense green light, blue light, and red light, respectively, and the detected information is transmitted by a transmission transistor. In addition, charge storage 55 is electrically connected to photoelectric conversion device 100, and the information of charge storage 55 is transmitted by the transmission transistor.

Metal wires and pads are provided on semiconductor substrate 310, but the metal wires and pads may be provided under photosensitive devices 50G, 50B, and 50R.

Lower insulation layer 60 is formed on semiconductor substrate 310 on which metal wires and pads are formed.

The material constituting lower insulation layer 60 may use the same material as the material constituting insulation layer 80.

Color filter layer 70 is formed on lower insulation layer 60.

Color filter layer 70 includes blue filter 70B formed in a blue pixel, green filter 70G formed in a green pixel, and red filter 70R formed in a red pixel.

Upper insulation layer 80 is formed on color filter layer 70 so as to planarize by removing steps by color filter layer 70.

In upper insulation layer 80 and lower insulation layer 60, contact holes exposing the pads and through-holes 85 exposing charge storage 55 are formed.

Photoelectric conversion device 100 is formed on upper insulation layer 80.

Photoelectric conversion device 100 includes first electrode 10, photoelectric conversion film 30, and second electrode 20 as described above. Herein, first electrode 10 is a light-transmitting electrode capable of transmitting visible light. In addition, second electrode 20 is a light-transmitting electrode capable of transmitting visible light and near-infrared light. Therefore, when light including near-infrared light and visible light is incident from second electrode 20 side, near-infrared light is absorbed in the photoelectric conversion film 30 to be photo-electrically converted. On the other hand, the light that is not absorbed in photoelectric conversion film 30, for example, visible light passes through first electrode 10 and color filter layer 70, and is detected by photosensitive devices 50G, 50B, and 50R.

In addition, a band pass filter that transmits only visible light and near-infrared light may be installed in the upper surface of the photoelectric conversion device 100.

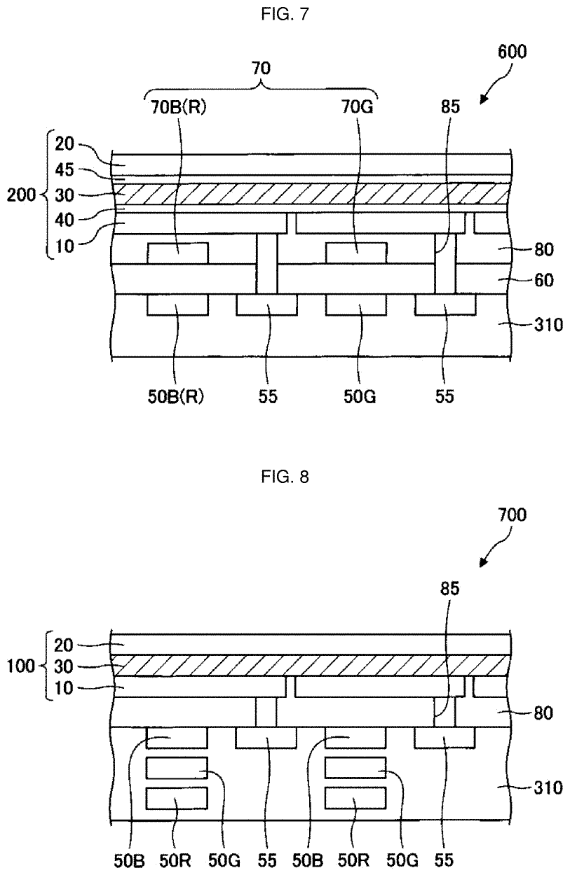

FIG. 7 shows a fourth example of an image sensor according to an embodiment.

Image sensor 600 has the same configuration as image sensor 500 except that photoelectric conversion device 200 is applied instead of photoelectric conversion device 100.

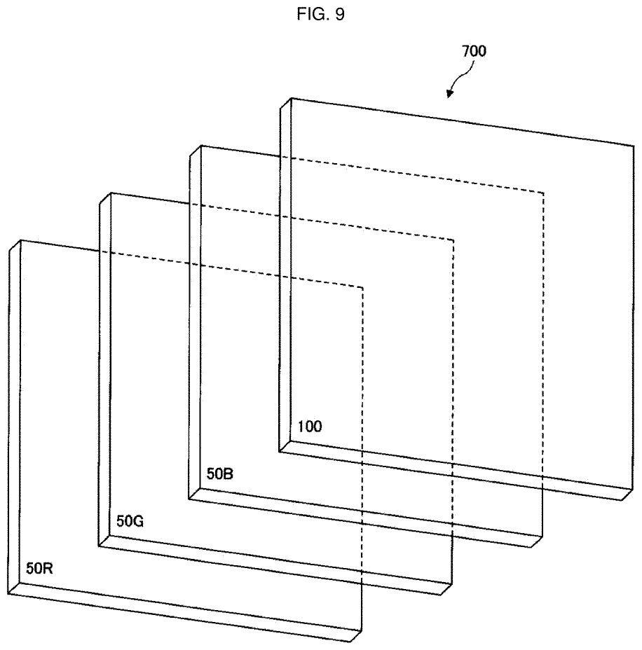

FIGS. 8 and 9 show a fifth example of an image sensor according to an embodiment.

Image sensor 700, like image sensor 500, includes semiconductor substrate 310, insulation layer 80, and photoelectric conversion device 100, and in semiconductor substrate 310, photosensitive devices 50G, 50B, and 50R, a transmission transistor, charge storage 55 are integrated.

However, unlike image sensor 500, image sensor 700 includes photosensitive devices 50B, 50G and 50R which are stacked, and color filter layer 70 is omitted.

Photosensitive devices 50B, 50G and 50R are electrically connected to the charge storage, and the information of the charge storage is transmitted by the transmission transistor.

Photosensitive devices 50B, 50G and 50R may selectively absorb blue light, green light, and red light, respectively, depending on a stacking depth.

Image sensor 700 may be down-sized because photoelectric conversion device 100 and photosensitive devices 50B, 50G, and 50R are stacked.

Instead of photosensitive devices 50G, 50B, and 50R, organic photoelectric conversion devices capable of selectively absorbing green light, blue light, and red light may be used. As a result, the sensitivity of the image sensor may be improved, and crosstalk may be reduced. In this case, the order of stacking photoelectric conversion device 100 and the organic photoelectric conversion devices capable of selectively absorbing green light, blue light, and red light is not particularly limited.

In addition, instead of photoelectric conversion device 100, photoelectric conversion device 200 may be applied.

The image sensor according to an embodiment may be applied to various electronic devices, such as, a mobile phone, a digital camera, and the like.

### EXAMPLES

Examples of an embodiment of the present disclosure are described. However, such examples are for illustration, and the technical ranges of the present disclosure are not limited to these examples.

### Synthesis Example 1: Synthesis of SnNc-[OSi(Hex)₃]₂

(Synthesis of SnNc)

SnNc-Cl₂ (2 gram) (Tokyo Kasei Ltd.) and NaBH₄ (0.76 gram) in pyridine are stirred under reflux for 5 hours, and then the reaction mixture is cooled to room temperature. Subsequently, water is added thereto, stirred under reflux for 1 hour, and then is cooled to room temperature. Then, the precipitates are filtered, and washed by methanol and water to obtain SnNc (1.6 gram).

(Synthesis of SnNc-I₂)

The prepared SnNc (1.6 gram) and I₂ (1.5 gram) in anhydrous 1-chloronaphthalene are stirred under reflux for 1 hour, and then is cooled to room temperature. Then, the precipitates are filtered, and washed with chloroform, pyridine, and methanol to obtain SnNc-I₂ (2.0 gram).

(Synthesis of SnNc-(OH)₂)

The prepared SnNc-I₂ (2.0 gram) and ammonium aqueous solution (0.3 milliliters) in pyridine are stirred under reflux for 5 hours, and then the reaction mixture is cooled to room temperature. Subsequently, the precipitates are filtered, and washed with pyridine to obtain SnNc-(OH)₂ (1.3 gram).

(Synthesis of n-(C₆H₁₃)₃SiOH)

(n-C₆H₁₃)₃SiCl (Aldrich Company Ltd.) (5 gram) and 10% ammonium aqueous solution (24 milliliters) in tetrahydrofuran are stirred under reflux for 2 hours, and then the reaction mixture is cooled to room temperature. Subsequently, the product is extracted with chloroform, and washed with water to obtain n-(C₆H₁₃)₃SiOH) (3 grams).

(Synthesis of SnNc-[OSi (Hex)₃]₂)

The prepared SnNc-(OH)₂ (0.5 gram) and n-(C₆H₁₃)₃SiOH) in 1,2,4-trimethylbenzene are stirred under reflux for 5 hours, and then the reaction mixture is cooled to room temperature. Subsequently, the precipitates are filtered, and washed with methanol to obtain of SnNc-[OSi (Hex)₃]₂ (0.6 gram).

### Synthesis Example 2: Synthesis of SnNc-[OSi(Bu)₃]₂

(Synthesis of n-(C₄H₉)₃SiOH)

(n-C₄H₉)₃SiCl (Aldrich Company Ltd.) (5 gram) and 10% ammonium aqueous solution (24 milliliters) in tetrahydrofuran are stirred under reflux for 2 hours, and then the reaction mixture is cooled to room temperature. Subsequently, the product is extracted with chloroform, and washed with water to obtain n-(C₄H₉)₃SiOH) (3 grams).

(Synthesis of SnNc-[OSi (Bu)₃]₂)

The prepared SnNc-(OH)₂ (0.5 gram) and n-(C₄H₉)₃SiOH in 1,2,4-trimethylbenzene are stirred under reflux for 5 hours, and then the reaction mixture is cooled to room temperature. Subsequently, the precipitates are filtered, and washed with methanol to obtain of SnNc-[OSi (Bu)₃]₂ (0.5 gram).

### Synthesis Example 3: Synthesis of SnNc-[OSi(Me)₃]₂

(Synthesis of (CH₃)₃SiOH)

(CH₃)₃SiCl (Aldrich Co. Ltd.) (6 gram) and 10% ammonium aqueous solution (28 milliliters) in tetrahydrofuran are stirred under reflux for 2 hours, and then the reaction mixture is cooled to room temperature. Subsequently, the product is extracted with chloroform, and washed with water to obtain n-(CH₃)₃SiOH) (3 grams).

(Synthesis of SnNc-[OSi (Me)₃]₂)

SnNc-(OH)₂ (0.5 gram) prepared in Synthesis Example 1 and the prepared (CH₃)₃SiOH in 1,2,4-trimethylbenzene are stirred under reflux for 5 hours, and then the reaction mixture is cooled to room temperature. Subsequently, the precipitates are filtered, and washed with methanol to obtain of SnNc-[OSi (Me₃]₂ (0.5 gram).

### Examples 1 to 8 and Comparative Examples 1 to 3

### Example 2: Manufacture of Photoelectric Conversion Device

An electron blocking layer is formed by thermally depositing Compound A represented by Chemical Formula A to be 20 nm thick on a glass substrate adhered with ITO (a film thickness: 150 nm).

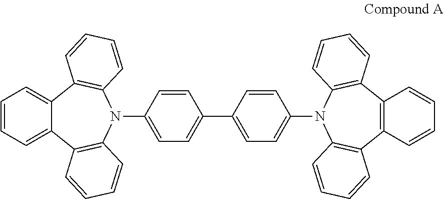 [SMILES: c1ccc2c(c1)-c1ccccc1N(c1ccc(-c3ccc(N4c5ccccc5-c5ccccc5-c5ccccc54)cc3)cc1)c1ccccc1-2]

Subsequently, a photoelectric conversion film is formed to be 150 nm thick by depositing a p-type organic semiconductor (a near-infrared absorption colorant; refer to Table 1), or a p-type organic semiconductor and fullerene C60 as an n-type organic semiconductor having a desired and/or alternative predetermined p/n ratio (refer to Table 1) in a resistive heating deposition method. In addition, on the photoelectric conversion film, an ITO layer is formed to be 10 nm thick in a high frequency magnetron sputtering method, obtaining a photoelectric conversion device.

Herein, a vacuum degree in a vacuum process is set to be less than or equal to 4×10⁻⁴ Pa.

Evaluation 1: λₘₐₓ, Abs₁₀₀₀ₙₘ, and E_{g} of Photoelectric Conversion Device

The absorption spectrums of the photoelectronic conversion layers having a thickness of 150 nm according to the Examples and Synthesis Examples are measured by using UV-Visible spectrophotometer UV-1900 (Shimadzu Corporation) and Multichannel photo detector MCPD-9800 (Otsuka Electronics Co. Ltd.) to obtain the maximum absorption wavelength, λₘₐₓ.

Further, Abs₁₀₀₀ₙₘ, which is the absorption of the photoelectronic conversion layers having a thickness of 100 nm with respect to the wavelength of 1,000 nm, is calculated by converting the thickness of 150 nm of the photoelectronic conversion layer to 100 nm.

Meanwhile, the band gap E_{g} of the photoelectronic conversion layers is assumed from the end of the longest wavelength of the absorption spectrum of the photoelectronic conversion layers. The band gap E_{g} is the difference between the ionization potential and electron affinity.

### Evaluation 2: Dark Current and External Quantum Efficiency (IPCE) of Photoelectric Conversion Device

The photoelectric conversion devices according to the Examples and Comparative Examples are sent into a glove box, without being exposed to the air, where each concentration of moisture and oxygen is maintained at less than or equal to 1 ppm, and the glove box is sealed with a glass sealing can having an adherent on by using a UV curing resin.

While a minus bias voltage of 3 V is respectively applied to the lower electrodes of the photoelectric conversion devices by using an IPCE-measuring system (Mcscience Inc.), external quantum efficiency (IPCE) at a maximum value of conversion efficiency in a wavelength range from 780 nm to 1,100 nm is measured. Here, if the dark current of the photoelectric conversion devices is less than or equal to 10⁻⁵ A/cm², measurement of ICPE is stabilized. However, if the dark current of the photoelectric conversion devices is greater than or equal to 10⁻⁴ A/cm², measurement of ICPE may be unstabilized.

λₘₐₓ, Abs₁₀₀₀ₙₘ, E_{g}, dark current, and IPCE evaluation results of the photoelectric conversion devices are shown in Table 1.

TABLE 1

| | | | | | | Photoelectronic | |
|---|---|---|---|---|---|---|---|
| | Photoelectronic conversion film | | | | | conversion device | |
| | p-type organic | p/n | λₘₐₓ | | E_{g} | Dark current | IPCE |
| | semiconductor | ratio | [nm] | Abs_{1000 nm} | [eV] | [A/cm²] | [%] |
| Example 1 | SiNc- | — | 794 | 0.06 | 1.43 | 6.72 × 10⁻¹⁰ | 1 |
| | [OSi(Hex)₃]₂ | | | | | | |
| Example 2 | SiNc- | 1 | 796 | 0.05 | 1.22 | 2.72 × 10⁻⁸ | 40 |
| | [OSi(Hex)₃]₂ | | | | | | |
| Example 3 | SnNc- | — | 818 | 0.06 | 1.32 | 1.60 × 10⁻⁹ | 1 |
| | [OSi(Hex)₃]₂ | | | | | | |
| Example 4 | SnNc- | 1 | 820 | 0.06 | 1.32 | 1.90 × 10⁻⁹ | 40 |
| | [OSi(Hex)₃]₂ | | | | | | |
| Example 5 | SnNc- | 0.5 | 821 | 0.05 | 1.32 | 1.73 × 10⁻⁹ | 50 |
| | [OSi(Hex)₃]₂ | | | | | | |
| Example 6 | SnNc- | 0.33 | 820 | 0.05 | 1.31 | 1.26 × 10⁻⁹ | 62 |
| | [OSi(Hex)₃]₂ | | | | | | |
| Example 7 | SnNc- | 1 | 828 | 0.13 | 1.10 | 1.26 × 10⁻⁶ | 33 |
| | [OSi(Bu)₃]₂ | | | | | | |
| Example 8 | SnNc- | 1 | 832 | 0.13 | 1.07 | 1.40 × 10⁻⁵ | 30 |
| | [OSi(Me)₃]₂ | | | | | | |
| Comparative | SnNc-Cl₂ | 1 | 870 | 0.16 | 1.03 | 1.50 × 10⁻⁴ | 30 |
| Example 1 | | | | | | | |
| Comparative | SnNc | 1 | 860 | 0.17 | 0.98 | 8.48 × 10⁻⁴ | 19 |
| Example 2 | | | | | | | |
| Comparative | SnNc | 0.8 | 860 | 0.17 | 1.00 | 4.74 × 10⁻⁴ | 20 |
| Example 3 | | | | | | | |

The abbreviations of the p-type organic semiconductor are as below, and the ‘pin ratio’ indicates the volume ratio of the p-type organic semiconductor to the n-type organic semiconductor. Further, ‘-’ of the p/n ratio means that the n-type organic semiconductor is not included.

SiNc-[OSi(Hex)₃]₂: Silicon 2,3-naphthalocyanine bis(tri-hexyl silyl oxide) (produced by Aldrich Co. Ltd.)

SnNc-[OSi(Hex)₃]₂: Tin 2,3-naphthalocyanine bis(tri-hexyl silyl oxide)

SnNc-[OSi(Bu)₃]₂: Tin 2,3-naphthalocyanine bis(tri-butyl silyl oxide)

SnNc-[OSi(Me)₃]₂: Tin 2,3-naphthalocyanine bis(tri-methyl silyl oxide)

SnNc-Cl2: Tin 2,3-naphthalocyanine dichloride (produced by Aldrich Co. Ltd.)

SnNc: Tin naphthalocyanine (produced by Aldrich Co. Ltd.)

Referring to Table 1, the photoelectric conversion device of Example 2 exhibits high IPCE anywhere in the wavelength range of 810 nm and 940 nm.

On the contrary, the photoelectric conversion devices according to Examples 1 to 8 exhibit low dark current. Further, the photoelectric conversion devices according to Examples 2, and 4 to 8 show high IPCE, as they have the photoelectronic conversion films including the p-type organic semiconductor and n-type organic semiconductor.

On the contrary, the photoelectric conversion devices according to Comparative Examples 1 to 3 exhibit high dark current, as they show Abs_{1000 nm}, which is the absorption of 1,000 nm, of 0.16 to 0.17.

The photoelectric conversion devices according to Examples 1 to 8 may be advantageously used in an image sensor as they produce low dark current. Further, from the simulated results when applied to an image sensor of a 3D scanner, it is confirmed that the photoelectric conversion devices according to Examples 1 to 7, which have dark current of less than or equal to 10⁻⁶ A/cm², may obtain 3-dimensional data with sufficient precision.

While this disclosure has been described in connection with what is presently considered to be practical example embodiments, it is to be understood that inventive concepts are not limited to the disclosed embodiments. On the contrary, inventive concepts are intended to cover various modifications and equivalent arrangements included within the spirit and scope of the appended claims.

### DESCRIPTION OF SYMBOLS

10: first electrode
20: second electrode
30: photoelectric conversion film
100, 200: photoelectric conversion device
300, 400, 500, 600, 700: image sensor

What is claimed is:

1. A photoelectric conversion film comprising:
a p-type organic semiconductor, which is a near-infrared light absorbing colorant, and having an absorption coefficient of light of less than or equal to 0.13 with respect to the wavelength of 1,000 nm at a thickness of 100 nm.

2. The photoelectric conversion film according to claim 1, wherein a difference between an ionization potential of the photoelectric conversion film and an electron affinity of the photoelectric conversion film is greater than or equal to 1.07 electron volts.

3. The photoelectric conversion film according to claim 2, wherein the difference between the ionization potential of the photoelectric conversion film and the electron affinity of the photoelectric conversion film is greater than or equal to 1.10 electron volts.

4. The photoelectric conversion film according to claim 1, wherein the p-type organic semiconductor includes a cyanine compound, a dipyrromethene compound, a squarilium compound, a diimmonium compound, a dithienyl complex, or a combination thereof.

5. The photoelectric conversion film according to claim 4, wherein the cyanine compound includes zinc phthalocyanine, Mn (II) phthalocyanine, silicon 2,3-naphthalocyanine bis(tri-hexyl silyl oxide), tin 2,3-naphthalocyanine bis(tri-hexyl silyl oxide), tin 2,3-naphthalocyanine bis(tri-butyl silyl oxide), tin 2,3-naphthalocyanine bis(tri-methyl silyl oxide), or a combination thereof.

6. The photoelectric conversion film according to claim 4, wherein the dipyrromethene compound includes dipyrromethene boron complex, di-benzo pyrromethene boron complex, or a combination thereof.

7. The photoelectric conversion film according to claim 4, wherein the squarilium compound includes 2,4-bis(8-hydroxy-1,1,7,7-tetramethyl zulorydin-9-yl) squarane.

8. The photoelectric conversion film according to claim 4, wherein the diimmonium compound includes N,N,N′,N′-tetrakis[p-bis(cyclohexylmethyl)aminophenyl]-p-phenylene diimmonium salt.

9. The photoelectric conversion film according to claim 4, wherein the dithienyl complex includes bis(4-dimethylaminodithiobenzyl) nickel (II), bis[4,4′-dimethoxy (dithiobenzyl)] nickel (II), or a combination thereof.

10. The photoelectric conversion film according to claim 1, which further comprising:
an n-type organic semiconductor.

11. The photoelectric conversion film according to claim 10, wherein the n-type organic semiconductor includes fullerene, a derivative of fullerene, or a combination thereof.

12. The photoelectric conversion film of claim 1, which is formed by a vacuum deposition method.

13. A photoelectric conversion device comprising
a first electrode,
a second electrode facing the first electrode, and
the photoelectric conversion film according to claim 1, between the first electrode and the second electrode.

14. The photoelectric conversion device of claim 13, further comprising:
an electron blocking layer between the first electrode and the photoelectric conversion film,
a hole blocking layer between the second electrode and the photoelectric conversion film, or
an electron blocking layer between the first electrode and the photoelectric conversion film and a hole blocking layer between the second electrode and the photoelectric conversion film.

15. An image sensor comprising:
the photoelectric conversion device of claim 13.

16. The image sensor of claim 15, further comprising:
one or more of a blue pixel, a green pixel, and a red pixel, wherein
the blue pixel, the green pixel, and the red pixel include a blue photosensitive device, a green photosensitive device, and a red photosensitive device, respectively.

17. The image sensor of claim 16, wherein at least one of the blue photosensitive device, the green photosensitive device, and the red photosensitive device is a silicon photodiode.

18. The image sensor of claim 16, wherein at least one of the blue photosensitive device, the green photosensitive device, and the red photosensitive device is an organic photoelectric conversion device that is configured to selectively absorb one or more of blue light, green light, and red light.

19. The image sensor of claim 16, wherein
the image sensor includes at least two of the blue photosensitive device, the green photosensitive device, and the red photosensitive device,
wherein the at least two of the blue photosensitive device, the green photosensitive device, or the red photosensitive device are stacked.
